(19) United States
(12) Patent Application Publication
(10) Pub. No.: US 2016/0240464 A1
(43) Pub. Date: Aug. 18, 2016

(54) HYBRID CIRCUIT BOARD AND METHOD FOR MAKING THE SAME, AND SEMICONDUCTOR PACKAGE STRUCTURE

(71) Applicants: HongQiSheng Precision Electronics (QinHuangDao) Co., Ltd., Qinhuangdao (CN); FuKui Precision Component (Shenzhen) Co., Ltd., Shenzhen (CN); Zhen Ding Technology Co., Ltd., Tayuan (TW)

(72) Inventor: YU-CHENG HUANG, New Taipei (TW)

(21) Appl. No.: 14/802,451

(22) Filed: Jul. 17, 2015

(30) Foreign Application Priority Data
Feb. 12, 2015 (CN) 201510074392.0

(51) Int. Cl. H01L 23/498; H01L 21/288; H01L 21/48; H01L 21/768; H01L 21/56

(52) U.S. Cl. CPC H01L 23/49827; H01L 23/49838; H01L 21/76879; H01L 21/565; H01L 23/49894; H01L 23/49866; H01L 21/486; H01L 21/2885

(57) ABSTRACT

A hybrid circuit board includes an insulate molding layer having a first surface and a second surface which is opposite to the first surface, a solder mask layer on the first surface, a conductive patterned layer on the first surface and embedded in the solder mask layer, and a plurality of conductive pillars embedded in the insulate molding layer. The thickness of the conductive patterned layer is substantially equal to the thickness of the solder mask layer. Each of conductive pillars has a first end electrically connected to the conductive patterned layer and a second end exposing to the insulated molding layer. The hybrid circuit board is cheap and can effectively avoid the warping of semiconductor packaging structure. A method for making the hybrid circuit board and a semiconductor packaging structure using the hybrid circuit board are also provided.

### FIELD

The subject matter herein generally relates to a package substrate structure.

### BACKGROUND

In the field of integrated circuit (IC) substrate packages, the package structure generally includes a substrate and a semiconductor chip electrically connected to the substrate. However, the thermal expansion coefficient of the semiconductor chip and the thermal expansion coefficient of the conventional substrate are different resulting in a warpage of the package structure and a low package yield rate.

### BRIEF DESCRIPTION OF THE DRAWINGS

Implementations of the present technology will now be described, by way of example only, with reference to the attached figures.

FIG. 1 is a cross sectional view of a hybrid circuit board according to the first embodiment of the present disclosure.

FIG. 2 is a cross sectional view of a hybrid circuit board according to the second embodiment of the present disclosure.

FIG. 3 is a cross sectional view of a semiconductor package structure according to the present disclosure.

FIG. 4A to FIG. 4F are cross sectional views of a method of making a hybrid circuit board in FIG. 1 according to the present disclosure.

FIG. 5A to FIG. 5C are cross sectional views of a method of making a hybrid circuit board in FIG. 2 based on the method of FIG. 4 according to the present disclosure.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein may be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

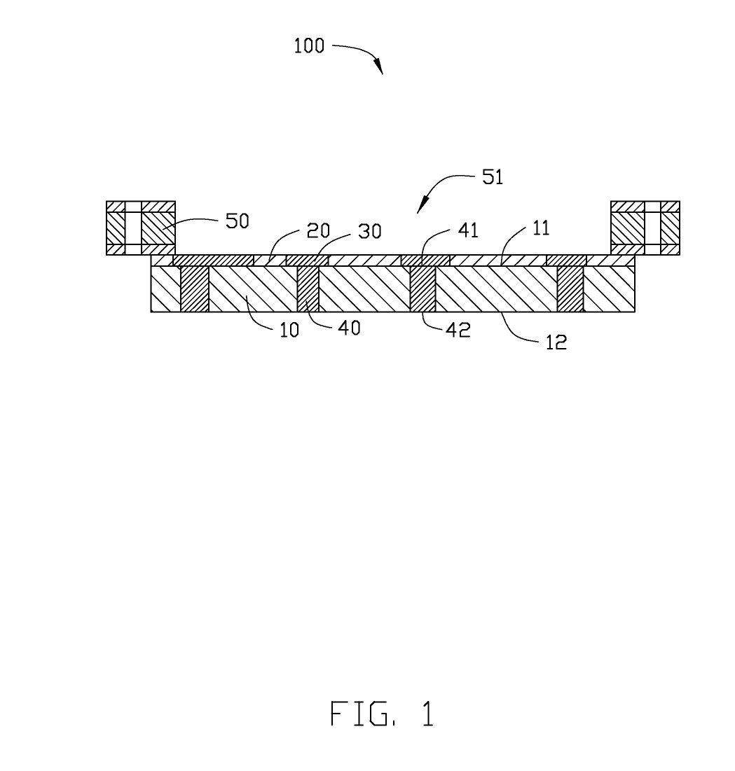

FIG. 1 illustrates a hybrid circuit board 100 including an insulated molding layer 10, a solder mask layer 20, a conductive patterned layer 30, a plurality of conductive pillars 40, and a supporting plate 50. The insulated molding layer 10 includes a first surface 11 and a second surface 12 opposite to the first surface 11. The solder mask layer 20 is formed on the first surface 11 of the insulated molding layer 10. The conductive patterned layer 30 is formed on a first surface 11 of the insulated molding layer 10 and is embedded in the solder mask layer 20. The thickness of the conductive patterned layer 30 is substantially equal to the thickness of the solder mask layer 20. The plurality of conductive pillars 40 are embedded in the insulated molding layer 10. Each of the conductive pillars 40 has a first end 41 electrically connected to the conductive patterned layer 30, and a second end 42 which is opposite to the first end 41 and is exposed to the second surface 12 of the insulated molding layer 10. The supporting plate 50 defines an opening 51 formed on the solder mask layer 20 and the conductive patterned layer 30 to partially expose the solder mask layer 20 and the conductive patterned layer 30. The second end 42 for each of the conductive pillars 40 is flush with the second surface 12 of the insulated molding layer 10, or is projecting from the second surface 12 of the insulated molding layer 10.

The solder mask layer 20 is formed by using conventional soldering resist inks The insulated molding layer 10 can be made by epoxy resin or hybrid epoxy. In this embodiment, the insulated molding layer 10 is made by epoxy resin. The thermal expansion coefficient of the insulated molding layer 10 is in a range of 3 ppm/° C.-6 ppm/° C. The thermal expansion coefficient of the insulated molding layer 10 is equivalent to the thermal expansion coefficient of semiconductor chips, which have a thermal expansion coefficient around 3 ppm/° C.-4 ppm/° C. . Using the insulated molding layer 10 in the hybrid circuit board 100 can effectively reduce the warpage of the semiconductor package structure. The cost of the epoxy resin used in the insulated molding layer 10 is much cheaper than the cost of conventional copper clad laminates (CCL) or polypropylene (PP).

The conductive materials used in the conductive patterned layer 30 and the conductive pillars 40 can be the conventional conductive metals, including copper, tin, nickel, chromium, titanium, and combined metal alloy of above. Copper is used in the illustrated embodiment.

The supporting plate 50 has sufficient stiffness and strength to prevent bending deformation damage to the hybrid circuit board 100 during transportation making the hybrid circuit board 100 easy to transport. In the illustrated embodiment, the supporting plate 50 may be a polymer sheet covered with the copper layers.

The portions of the solder mask layer 20 and the conductive patterned layer 30, corresponding to the opening 51 of the supporting plate 50, are exposed and formed as a chip bonding region (not shown).

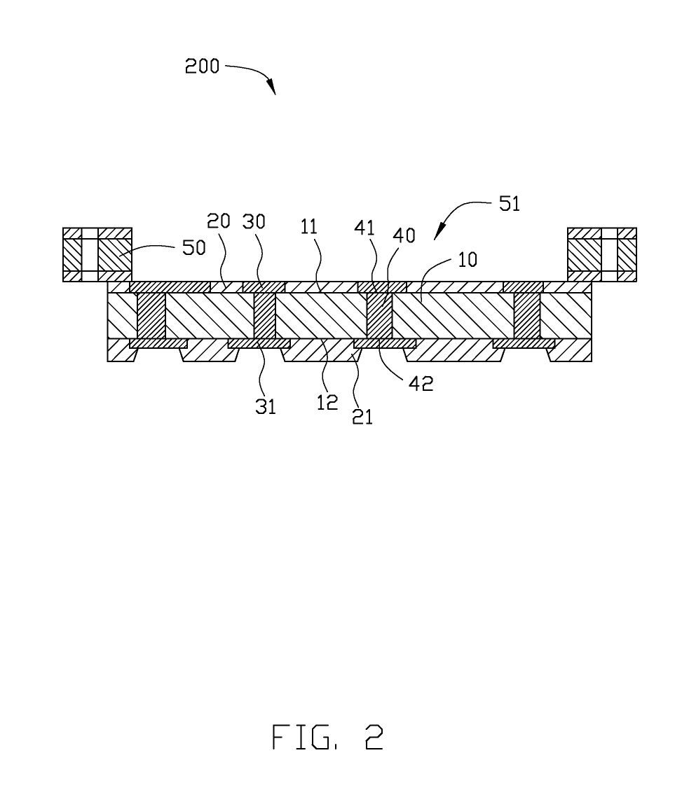

FIG. 2 illustrates a second embodiment of the hybrid circuit board 200, which has an additional second solder mask layer 21 and a second conductive patterned layer 31 based on the structure of the hybrid circuit board 100. The second conductive patterned layer 31 is formed on the second surface 12 of the insulated molding layer 10, and the second solder mask layer 21 is formed on the second surface 12 of the insulated molding layer 10 and a portion of the second conductive patterned layer 31. A partial surface of the second conductive patterned layer 31 is exposed to the second solder mask layer 21. The second conductive patterned layer 31 is electrically connected with the second ends 42 of the conductive pillars 40.

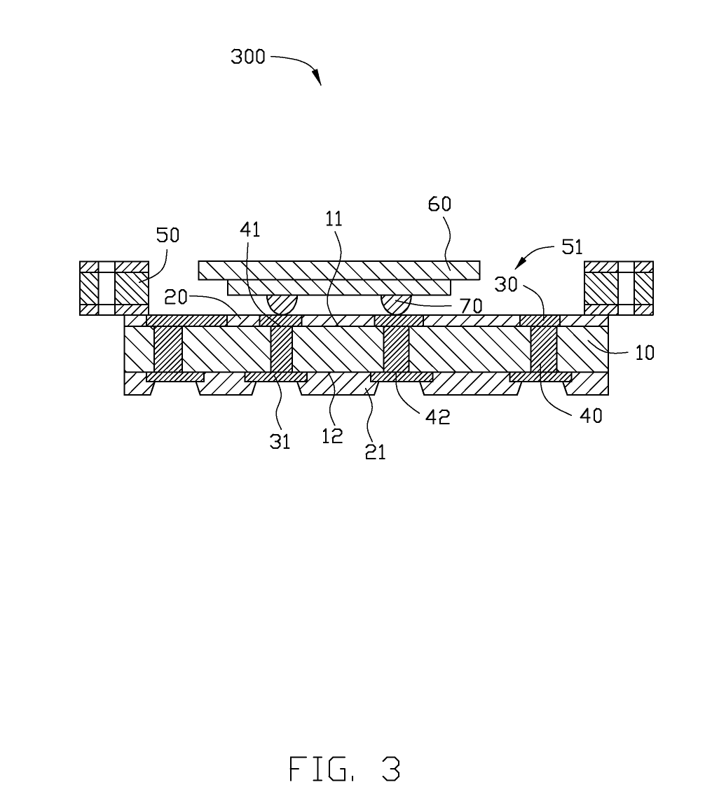

FIG. 3 illustrates a semiconductor package structure 300, which includes the hybrid circuit board 200 and a semiconductor chip 60. The semiconductor chip 60 is electrically connected with the conductive patterned layer 30 by solder 70. In this embodiment, the semiconductor chip 60 can be a flip-chip or a wire-bond chip.

It is necessary to fill in underfills (not shown) when using a flip-chip at the junction between the hybrid circuit board 200 and the flip-chip 60. The underfills can be wrapped around the solder 70 to protect the solder 70 and can be used to enhance the bonding force between the flip-chip 60 and the hybrid circuit board 200.

In other embodiments, the hybrid circuit board 200 of the semiconductor package structure 300 can be replaced by the hybrid circuit board 100.

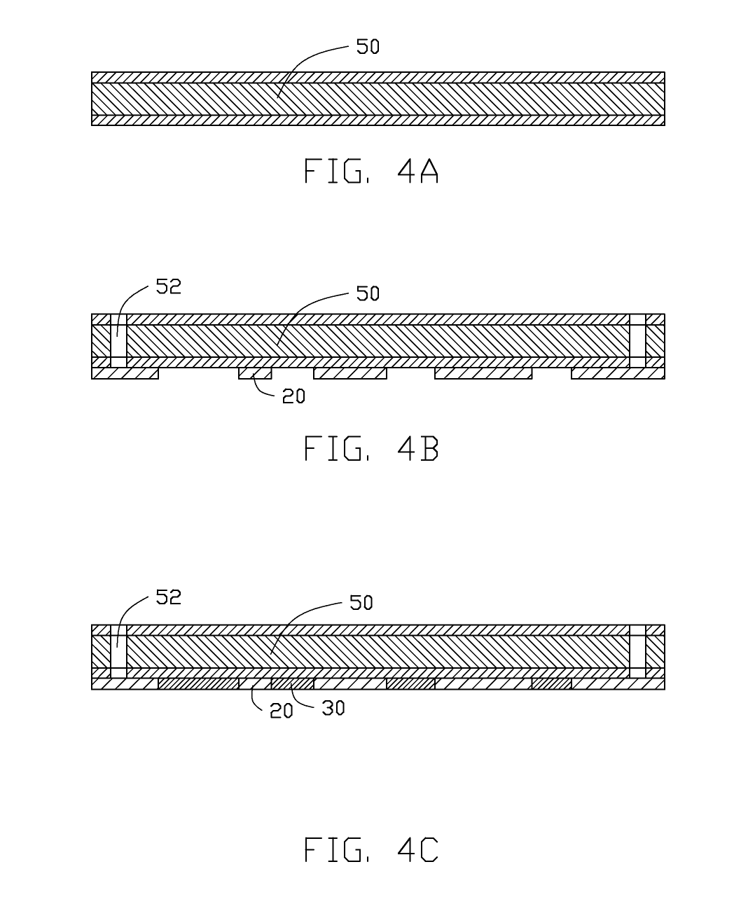

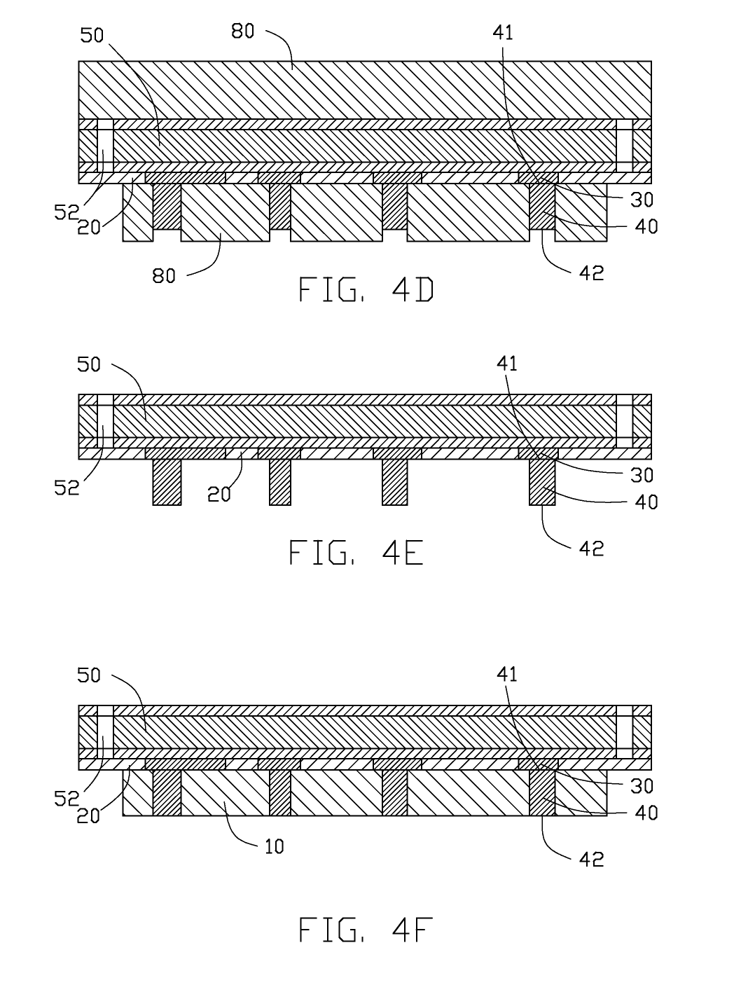

FIG. 4A to FIG. 4F illustrates a method of making the hybrid circuit board 100.

Referring to FIGS. 4A to 4F, a process flow is presented in accordance with an example embodiment. The example method shown in FIGS. 4A to 4F is provided by way of example, as there are a variety of ways to carry out the method. The method described below can be carried out using the configurations illustrated in FIGS. 4A to 4F, for example, and various elements of these figures are referenced in explaining example method. Each of FIGS. 4A to 4F represents one or more processes, methods or subroutines, carried out in the example method. Furthermore, the illustrated order of FIGS. 4A to 4F is illustrative only and the order of FIG. 4A to 4F can change according to the present disclosure. Additional processes can be added or fewer processes may be utilized, without departing from this disclosure.

FIG. 4A illustrates a supporting plate 50, which has sufficient stiffness and strength for using as a carrier of the hybrid circuit board 100. In this embodiment, the supporting plate 50 is a polymer sheet covered with the copper metal layers as shown in FIG. 4A.

FIG. 4B illustrates the supporting plate 50 in FIG. 4A to open a through hole 52 and to form a solder mask layer 20. The solder mask layer 20 is formed on part of an end surface of the supporting plate 50. The process details for forming the sold mask layer are described as below. Firstly, one end surface of the supporting plate 50 is fully coated with the photosensitive solder resist ink, and then the photosensitive solder resist ink is exposed and developed to remove part of the photosensitive solder resist ink, and finally, the solder mask layer 20 is formed on part of the surface of the supporting plate 50.

Before coating the photosensitive solder resist ink, the supporting plate 50 can define a through hole 52. The through hole 52 shown in FIG. 4B is an example for illustration only and is not an actual position. After the through hole 52 is defined, the supporting plate 50 is coated with the photosensitive solder resist ink. After coating the photosensitive solder resist ink, the photosensitive solder resist ink positioned on the supporting plate 50 is exposed and developed to form the solder mask layer 20 on part of an end surface of the supporting plate 50. The light used for exposure can be an ultraviolet light.

FIG. 4C illustrates a conductive patterned layer 30 to be formed on the supporting plate 50 shown in FIG. 4B. The conductive patterned layer 30 is formed on the end surface of the supporting plate 50 with the solder mask layer 20, in addition, the conductive patterned layer 30 is formed on the end surface of the supporting plate 50 without covering the solder mask layer 20.

In the illustrated embodiment, the conductive patterned layer 30 can be formed by electro-plating. The conductive patterned layer 30 is embedded in the solder mask layer 20. The thickness of the conductive patterned layer 30 is equivalent to the thickness of the solder mask layer 20 as shown in FIG. 4C. The circuit pattern of the hybrid circuit board 100 can be well defined by the conductive patterned layer 30 and the solder mask layer 20 with a fine line circuit pattern. Therefore, the method of the present disclosure can be used to realize the preparation of the fine line circuit pattern.

FIG. 4D and FIG. 4E illustrate a plurality of conductive pillars 40 to be formed on the surface of the conductive patterned layer 30 shown in FIG. 4C. Each of the conductive pillars 40 has a first end 41 electrically connected with the conductive patterned layer 30, and a second end 42 opposite to the first end 41.

FIG. 4D illustrates that a dry film layer 80 is formed on the surface of the supporting plate 50 with the solder mask layer 20 and the conductive patterned layers 30, and another dry film layer 80 is formed on the surface of the supporting plate 50 away from the conductive patterned layer 30. The dry film layer 80, which is positioned on the surface of the supporting plate 50 with the solder mask layer 20 and the conductive patterned layer 30, is exposed and is developed to remove a portion of the dry film layer 80. After developing, the surface of the conductive patterned layer 30 is partially exposed. And then, a plurality of conductive pillars 40 are formed on the exposed surface of the conductive patterned layer 30, and are electrically connected with the conductive patterned layer 30. The method for making the conductive pillars 40 can be electroplating. And finally, the residual dry film layers 80 are removed and shown as FIG. 4E. In the illustrated embodiment, the electroplating method used for forming the conductive pillars replaces the traditional mechanical drilling method.

FIG. 4F illustrates an insulated molding layer 10 to be formed on the surface of the supporting plate 50 with the solder mask layer 20 and the conductive patterned layer 30 shown in FIG. 4E. The conductive pillars 40 are embedded in the insulated molding layer 10, and the second ends 42 of the conductive pillars 40 related to the insulated molding layer 10 are exposed.

To manufacture the insulated molding layer 10, the supporting plate 50 with the conductive patterned layer 30 electrically connected with a plurality of conductive pillars shown in FIG. 4E is first placed into a mold (not shown), the molten resin is injected to the surface of the supporting plate 50 with the solder mask layer 20 and the conductive patterned layer 30, to form the insulated molding layer 10 on the surface of the solder mask layer 20 and the conductive patterned layer 30. A plurality of the conductive pillars 40 are embedded in the insulated molding layer 10 as shown in FIG. 4F. After molding the insulated molding layer 10, it can further include a polishing process for polishing the mold surface of the insulated molding layer 10. After polishing, the second ends 42 of the conductive pillars 40 embedded in the insulated molding layer 10 are exposed.

Before manufacturing the insulated molding layer 10, the conductive pillars 40 can be micro-etched to produce rough surfaces on the conductive pillars 40. The rough surfaces of the conductive pillars 40 can enhance the bonding force between the conductive pillars 40 and the insulated molding layer 10.

The method for making the hybrid circuit board 100 further comprises a process that the supporting plate 50 is partially etched to form an opening 51 which exposes the solder mask layer 20 and the conductive patterned layer 30. As mentioned above, the partial etching process can use the dry film layer 80 for patterning to expose part of the supporting plate 50, and then, the exposed part of the supporting plate 50 is etched by the conventional chemical solutions to define the opening 51. The method for making a hybrid circuit board is easy to produce a thin hybrid circuit board, thereby reducing the overall thickness of the semiconductor package structure.

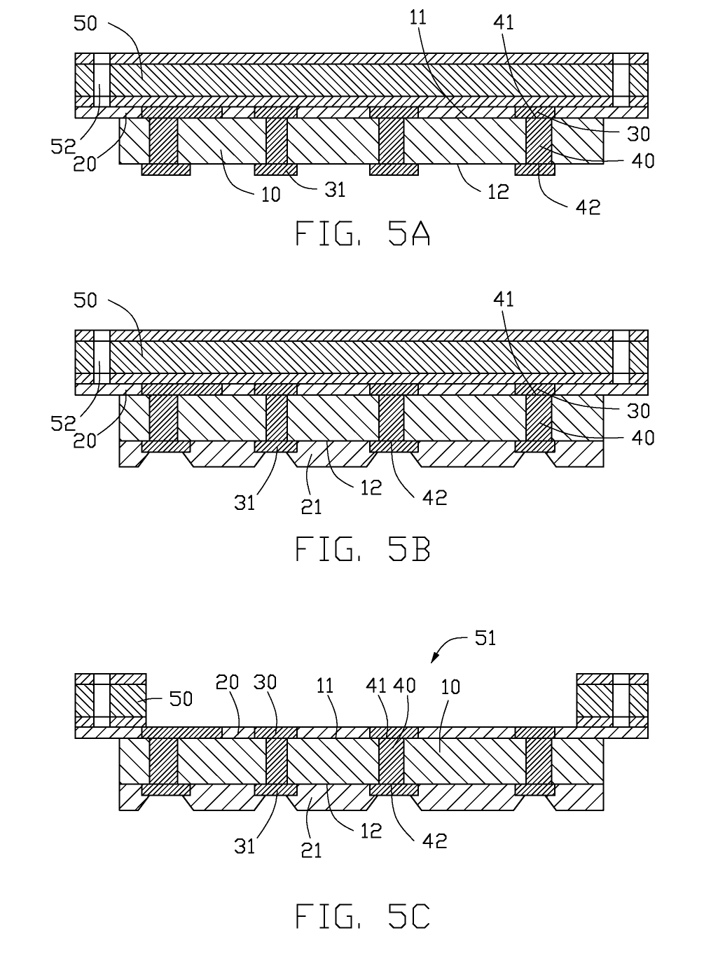

To produce a hybrid circuit board 200, it needs to perform additional procedures based on the structure of FIG. 4F. FIG. 5A to FIG. 5C illustrate the additional processes to form the second solder mask layer 21 and the second conductive patterned layer 31.

FIG. 5A illustrates a second conductive patterned layer 31 to be formed on the surface of the insulated molding layer 10 shown in FIG. 4F for electrical connection with the second ends 42 of the conductive pillars 40. The second conductive patterned layer 31 is partially etched to remove a portion of the second conductive patterned layer 31 and expose a portion of the insulated molding layer 10. The method of forming a second conductive patterned layer 31 can be selected from one of electro-plating, chemical deposition, or physical deposition.

FIG. 5B illustrates a second solder mask layer 21 to be formed on part of the second conductive patterned layer 31 and the exposed insulated molding layer 10 shown in FIG. 5A. The process details are described as follow. The exposed portion of the insulated molding layer 10 mentioned in FIG. 5A is coated with the photosensitive solder resist ink to form the second solder mask layer 21 after patterning.

The detailed method for partially etching the second conductive patterned layer 31 is described as below. The second conductive patterned layer 31 is fully covered with a dry film layer 80. The surface of the supporting plate 50 away from the conductive patterned layer 30 is also covered with a dry film layer 80 for protection. Next, the dry film layer 80 positioned on the second conductive patterned layer 31 is exposed and developed to remove part of the dry film layer 80 and to expose a portion of the second conductive patterned layer 31. The exposed portion of the second conductive patterned layer 31 is etched and removed. The etching method is a chemical etching by using the conventional etching solutions.

The method for making the hybrid circuit board 200 further comprises a process that the supporting plate 50 is partially etched to form an opening 51 which exposes the solder mask layer 20 and the conductive patterned layer 30 as shown in FIG. 5C. As mentioned above, the partial etching process can use the dry film layer 80 for patterning to expose part of the supporting plate 50, and then, the exposed part of the supporting plate 50 is etched by the conventional chemical solutions to define the opening 51.

An organic solderability preservative (OSP) is used to cover the surface of the conductive patterned layer 30 of the hybrid circuit board 100, or to cover the surfaces of the conductive patterned layer 30 and the second conductive patterned layer 31 of the hybrid circuit board 200, to protect the surface of the conductive patterned layer 30 and/or the second conductive patterned layer 31. In addition, a multi-metal layer of Ni/Pt/Au can be formed on the surface of the conductive patterned layer 30, or formed on the surfaces of the conductive patterned layer 30 and the second conductive patterned layer 31, to avoid the surface oxidation of the exposed portion of the conductive patterned layer 30 and the second conductive patterned layer 31.

With the present disclosure, a hybrid circuit board for semiconductor package structures and materials are an optimized design, which can include the introduction of an insulated molding layer 10 in the package substrate structure, and the design of the materials by matching the thermal expansion coefficient of the insulated molding layer 10 and the thermal expansion coefficient of the semiconductor chips 60. It is not only effective to reduce cost, but also effective to avoid warping of the package of the semiconductor package structure in the subsequent processes. In addition, the manufacturing method is simple to form a hybrid circuit board with a plurality of conductive pillars by using the electroplating process instead of the traditional mechanical drilling process, and achieve a fine line circuit pattern on a thinner hybrid circuit board, thereby reducing the overall thickness of the semiconductor package structure.

The embodiments shown and described above are only examples. Many details are often found in the art such as the other features of a hybrid circuit board. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, especially in matters of shape, size, and arrangement of the parts within the principles of the present disclosure, up to and including the full extent established by the broad general meaning of the terms used in the claims. It will therefore be appreciated that the embodiments described above may be modified within the scope of the claims.

1. A hybrid circuit board comprising:
an insulated molding layer comprising a first surface and a second surface opposite to the first surface;
a solder mask layer formed on the first surface of the insulated molding layer;
a conductive patterned layer formed on the first surface of the insulated molding layer and embedded in the solder mask layer, the solder mask layer having a thickness that is substantially equal to a thickness of the conductive patterned layer;
a plurality of conductive pillars embedded in the insulated molding layer, each of the plurality of conductive pillars has a first end electrically connected to the conductive patterned layer and a second end exposed to the second surface of the insulated molding layer; and
a supporting plate positioned on the solder mask layer with the embedded conductive patterned layer, the supporting plate forming an opening to partially expose the solder mask layer and the conductive patterned layer.

2. The hybrid circuit board of claim 1, wherein the second end for each of conductive pillars is flush with the second surface of the insulated molding layer, or the second end of each of conductive pillars is projecting from the second surface of the insulated molding layer.

3. The hybrid circuit board of claim 1, wherein the thermal expansion coefficient of the insulated molding layer is in a range of 3 ppm/° C.-6 ppm/° C.

4. The hybrid circuit board of claim 3, wherein the main composition of the insulated molding layer is selected from one of epoxy resins, hybrid epoxy resins, or mixed of above.

5. The hybrid circuit board of claim 1, wherein the conductive patterned layer and the conductive pillars are made of copper.

6. The hybrid circuit board of claim 1, wherein the hybrid circuit board further includes a second solder mask layer and a second conductive patterned layer, the second conductive patterned layer is formed on the second surface of the insulated molding layer, the second solder mask layer is formed on the second surface of the insulated molding layer and a portion of the second solder mask layer, a partial surface of the second conductive patterned layer is exposed to the second solder mask layer, and the second conductive patterned layer is electrically connected with the conductive pillars.

7. The hybrid circuit board of claim 1, wherein the exposed portions of the conductive patterned layer and the solder mask layer corresponding to the opening are used as a bonding area for bonding semiconductor chips.

8. A semiconductor package structure comprising:
a hybrid circuit board, comprising:
an insulated molding layer comprising a first surface and a second surface opposite to the first surface;
a solder mask layer formed on the first surface of the insulated molding layer;
a conductive patterned layer formed on the first surface of the insulated molding layer and embedded in the solder mask layer, the thickness of the solder mask layer is equivalent to the thickness of the conductive patterned layer;
a plurality of conductive pillars embedded in the insulated molding layer, each of conductive pillars has a first end electrically connected to the conductive patterned layer, and a second end exposed to the second surface of the insulated molding layer; and
a supporting plate positioned on the solder mask layer and the conductive patterned layer, the supporting plate has an opening to partially expose the solder mask layer and the conductive patterned layer; and
a semiconductor chip bonded on the opening which is corresponding to the exposed portions of the solder mask layer and the conductive patterned layer, the semiconductor chip is electrically connected to the conductive patterned layer,
wherein the thermal expansion coefficient of the insulated molding layer is equivalent to the thermal expansion coefficient of the semiconductor chip.

9. The semiconductor package structure of claim 8, wherein the thermal expansion coefficient of the insulated molding layer is in a range of 3 ppm/° C.-6 ppm/° C. .

10. The semiconductor package structure of claim 8, wherein the conductive patterned layer and the conductive pillars are made of copper.

11. The semiconductor package structure of claim 10, wherein the hybrid circuit board further includes a second solder mask layer and a second conductive patterned layer, the second conductive patterned layer is formed on the second surface of the insulated molding layer, the second solder mask layer is formed on the second surface of the insulated molding layer and a portion of the second conductive patterned layer, a partial surface of the second conductive patterned layer is exposed to the second solder mask layer, and the second conductive patterned layer is electrically connected with the conductive pillars.

12. A method of manufacturing a hybrid circuit board comprising the steps of :
providing a supporting plate;
forming a solder mask layer on part of an end surface of the supporting plate;
forming a conductive patterned layer on the end surface of the supporting plate, the conductive patterned layer is formed on the end surface of the supporting plate without covering the solder mask layer, the thickness of the solder mask layer is equivalent to the thickness of the conductive patterned layer;
forming a plurality of conductive pillars on the surface of the conductive patterned layer, each of conductive pillars has a first end to electrically connect with the conductive patterned layer, and a second end opposite to the first end;
forming an insulated molding layer on the surfaces of the supporting plate with the solder mask layer and the conductive patterned layer, the conductive pillars are embedded in the insulated molding layer, and the second end for each of conductive pillars related to the insulated molding layer is exposed; and
etching the supporting plate to form an opening for exposing partially the solder mask layer and the conductive patterned layer.

13. The method of manufacturing a hybrid circuit board of claim 12, wherein the method for forming the conductive patterned layer and the conductive pillars is electroplating.

14. The method of manufacturing a hybrid circuit board of claim 12, wherein the step for forming the solder mask layer comprises the further steps as:
to fully coat with the photosensitive solder resist ink on an end surface of the supporting plate, and then the photosensitive solder resist ink is exposed and developed to remove part of the photosensitive solder resist ink, and finally, the solder mask layer is formed on partial surface of the supporting plate.

15. The method of manufacturing a hybrid circuit board of claim 12, wherein the step for forming a plurality of conductive pillars comprises the further steps as:
to form the dry film layers on both surfaces of the supporting plate for protection;
to expose and develop the dry film layer positioned on the surface of the supporting plate with the solder mask layer and the conductive patterned layer, and to remove a portion of the dry film layer for exposing the partial surface of the conductive patterned layer;
to form a plurality of conductive pillars on the exposed surface of the conductive patterned layer, the conductive pillars are electrically connected with the conductive patterned layer; and
to remove the residual dry film layer.

16. The method of manufacturing a hybrid circuit board of claim 12, wherein the step for forming an insulated molding layer comprises further steps as:
to inject the molten resin to the surfaces of the solder mask layer and the conductive patterned layer for forming the insulated molding layer, and the conductive pillars are embedded in the insulated molding layer;
to polish the mold surface of the insulated molding layer for exposing the second ends of the conductive pillars.

17. The method of manufacturing a hybrid circuit board of claim 12, wherein the method further comprises a step prior to form the insulated molding layer, the step is to roughen the surfaces of conductive pillars by micro-etching.

18. The method of manufacturing a hybrid circuit board of claim 12, wherein the method further comprises the steps of:
forming a second conductive patterned layer on the insulated molding layer after molding the insulated molding layer, wherein the second conductive patterned layer is electrically connected with the conductive pillars;
etching the second conductive patterned layer to remove a portion of the second conductive patterned layer and to expose a portion of the insulated molding layer; and
forming a second solder mask layer on the exposed insulated molding layer after coating and patterning the solder resist ink layer.

19. The method of manufacturing a hybrid circuit board of claim 12, wherein a thermal expansion coefficient of the insulated molding layer is in a range of 3 ppm/° C-6 ppm/° C.

20. The method of manufacturing a hybrid circuit board of claim 19, wherein the main composition of the insulated molding layer is selected from one of epoxy resins, hybrid epoxy resins, or mixed of above.
